(19) United States
(12) Patent Application Publication
(10) Pub. No.: US 2026/0204518 A1
(43) Pub. Date: Jul. 16, 2026

(54) Plasma Processing Device

(71) Applicant: Tokyo Electron Limited, Tokyo (JP)

(72) Inventor: Takahiro SHINDO, Tokyo (JP)

(21) Appl. No.: 19/565,863

(22) Filed: Mar. 13, 2026

Related U.S. Application Data
(63) Continuation of application No. PCT/JP2024/032705, filed on Sep. 12, 2024.

(30) Foreign Application Priority Data
Sep. 25, 2023 (JP) 2023-161632

(51) Int. Cl. H01J 37/32

(52) U.S. Cl. CPC H01J 37/32174; H01J 37/32146; H01J 37/32541

(57) ABSTRACT

There is a plasma processing apparatus including a processing chamber; a first high-frequency power supply; a shower head electrically connected to the first high-frequency power supply and configured to receive a voltage from the first high-frequency power supply; a shaping circuit configured to supply the shower head with a shaped high-frequency voltage generated by cutting a positive voltage component of a high-frequency voltage from the first high-frequency power supply; a placing table disposed below the shower head and configured to support a wafer; a planar electrode disposed between the shower head and the placing table, extending along a surface of the placing table and including a plurality of conductive wires combined in a planar shape; a first potential setting circuit configured to set a potential of the planar electrode; and a second potential setting circuit configured to set a potential of the placing table.

### CROSS-REFERENCE TO RELATED APPLICATIONS

This application is a bypass continuation application of International Application No. PCT/JP2024/032705 having an international filing date of September 12, 2024 and designating the United States, the International Application being based upon and claiming the benefit of priority from Japanese Patent Application No. 2023-161632 filed on September 25, 2023, the entire contents of which are incorporated herein by reference.

### TECHNICAL FIELD

The exemplary embodiments of the present disclosure relate to a plasma processing apparatus.

### BACKGROUND

In manufacturing electronic devices such as semiconductor devices, a plasma processing apparatus is used, for example. In the plasma processing apparatus, a wafer is processed by irradiating ions in plasma to a wafer. Japanese Laid-open Patent Publication No. 2022-018062 discloses a technique for suppressing ion bombardment on a wafer.

### SUMMARY

The present disclosure provides a technique for reducing damage to a wafer that may occur when impact on the wafer caused by positive ions is suppressed.

In accordance with an exemplary embodiment of the present disclosure, there is a plasma processing apparatus. The plasma processing apparatus comprises a processing chamber, a first high-frequency power supply, a shower head, a shaping circuit, a placing table, a planar electrode, a first potential setting circuit, and a second potential setting circuit. The shower head is electrically connected to the first high-frequency power supply and is configured to receive a voltage applied from the first high-frequency power supply, the shower head serving as an upper electrode. The shaping circuit is configured to supply, to the shower head, a shaped high-frequency voltage generated by cutting a positive voltage component of a high-frequency voltage supplied from the first high-frequency power supply. The placing table is provided below the shower head and is configured to support a wafer, the placing table serving as a lower electrode. The planar electrode is provided in a space between the shower head and the placing table, the planar electrode extending along a surface of the placing table and comprising a plurality of conductive wires combined in a planar shape. The first potential setting circuit is configured to set a potential of the planar electrode. The second potential setting circuit is configured to set a potential of the placing table.

### BRIEF DESCRIPTION OF THE DRAWINGS

FIG. 1 is a diagram showing a plasma processing apparatus according to one exemplary embodiment.

FIG. 2 is a diagram showing a configuration of a potential setting circuit according to one example for setting a potential of a placing table shown in FIG. 1.

FIG. 3 is a diagram showing a configuration of a potential setting circuit according to another example for setting a potential of the placing table shown in FIG. 1.

FIG. 4 is a diagram showing a configuration of a potential setting circuit according to another example for setting a potential of the placing table shown in FIG. 1.

FIG. 5 is a diagram showing a configuration of a potential setting circuit according to one example for setting a potential of a planar electrode shown in FIG. 1.

FIG. 6 is a diagram showing a configuration of a potential setting circuit according to another example for setting a potential of the planar electrode shown in FIG. 1.

FIG. 7 is a diagram showing a configuration of a potential setting circuit according to another example for setting a potential of the planar electrode shown in FIG. 1.

FIG. 8 is an enlarged view illustrating a portion of the configuration of the planar electrode shown in FIG. 1.

### DETAILED DESCRIPTION

Hereinafter, various exemplary embodiments will be described.

In plasma processing, in order to suppress impact on a wafer caused by positive ions, it may be considered to cut positive voltage components of a high-frequency voltage used for plasma generation. In this case, a current may flow in a DC-pulsed manner through plasma from a conductive placing table on which a wafer is placed toward an upper electrode. However, when a wafer having an insulating film is placed on the placing table, the DC current does not pass through the wafer. Thus, the current may flow so as to avoid the wafer, from an outer peripheral portion of the wafer toward a central portion of the wafer along a radial direction of the wafer, and then flow through the plasma toward the upper electrode. As a result, a potential difference is generated in the plasma in the radial direction of the wafer, and the potential difference is transferred to the surface of the wafer, thereby causing a potential difference to be generated on the surface of the wafer in the radial direction of the wafer. Due to such a potential difference that may be generated in the radial direction, damage (charge-up damage) may be caused on the surface of the wafer. A plasma processing apparatus according to one exemplary embodiment provides a technique capable of reducing damage to a wafer that may occur by suppressing impact on the wafer caused by positive ions.

In other words, in one exemplary embodiment, a plasma processing apparatus is provided. The plasma processing apparatus includes a processing chamber, a first high-frequency power supply, a shower head, a shaping circuit, a placing table, a planar electrode, a first potential setting circuit, and a second potential setting circuit. The shower head is electrically connected to the first high-frequency power supply, and is configured to receive a voltage applied from the first high-frequency power supply, and serves as an upper electrode. The shaping circuit is configured to supply to the shower head a shaped high-frequency voltage generated by cutting positive voltage components of a high-frequency voltage supplied from the first high-frequency power supply. The placing table is provided below the shower head, is configured to place a wafer thereon, and serves as a lower electrode. The planar electrode is provided in a processing space between the shower head and the placing table, extends along the surface of the placing table, and is configured by combining a plurality of conductive wires in a planar shape. The first potential setting circuit is configured to set a potential of the planar electrode. The second potential setting circuit is configured to set a potential of the placing table.

In the plasma processing apparatus described above, the shaping circuit applies a high-frequency voltage in which a positive voltage component is cut, i.e., a shaped high-frequency voltage, to the shower head that is an upper electrode, so that the impact on the wafer caused by positive ions can be suppressed. In the plasma processing apparatus, the planar electrode to which a potential is provided is located in the processing space between the shower head and the placing table, and the planar electrode is a conductor configured by combining a plurality of conductive wires in a planar shape and is provided with a plurality of openings that connect an upper side and a lower side thereof. Accordingly, even when an insulating film is formed on the wafer, the current can flow from the planar electrode located above the wafer toward the shower head located above the wafer, without flowing along the radial direction of the wafer. Hence, no radial potential difference occurs on the surface of the wafer, so that it is possible to reduce damage to the wafer that may occur when impact on the wafer caused by positive ions is suppressed.

Hereinafter, various exemplary embodiments will be described in detail with reference to the accompanying drawings. Throughout the drawings, like reference numerals will be used for like or corresponding parts.

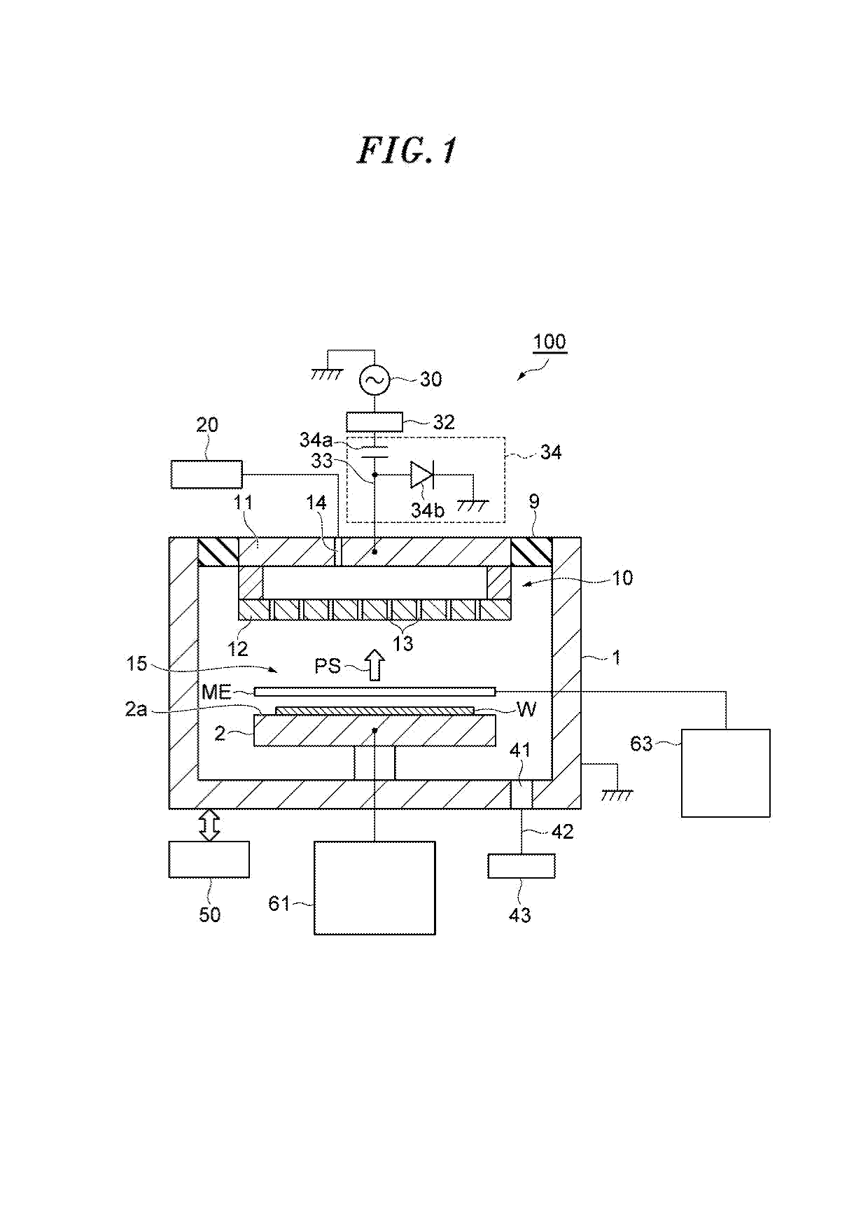

FIG. 1 is a diagram schematically illustrating a plasma processing apparatus according to one exemplary embodiment. A plasma processing apparatus 100 shown in FIG. 1 performs plasma processing on a wafer W. An insulating layer is formed on the surface of the wafer W.

The plasma processing apparatus 100 includes a processing chamber 1, a placing table 2, an insulating member 9, a shower head 10, a main body 11, a shower plate 12, gas injection holes 13, gas introducing holes 14, a gas supply part 20, an exhaust port 41, an exhaust line 42, and an exhaust device 43. The plasma processing apparatus 100 further includes a high-frequency power supply 30, a matching device 32, a power supply line 33, a shaping circuit 34, a controller 50, a potential setting circuit 61, and a potential setting circuit 63.

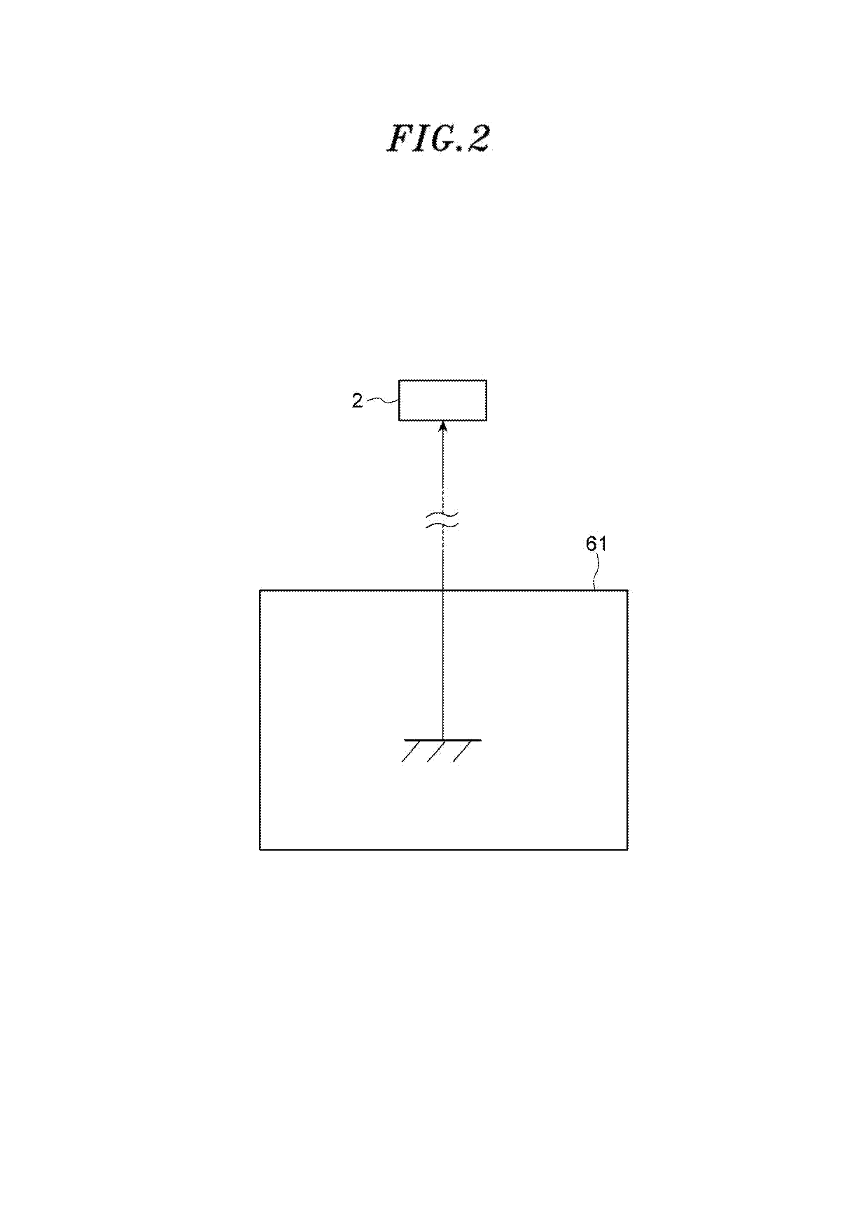

The plasma processing apparatus 100 has a substantially cylindrical processing chamber 1 made of a metal. The processing chamber 1 is electrically grounded. The placing table 2 is provided in the processing chamber 1 to be located below the shower head 10, and is configured to horizontally place the wafer W. The placing table 2 serves as a lower electrode, and is electrically connected to the potential setting circuit 61. The potential of the placing table 2 that is the lower electrode (hereinafter, simply referred to as “placing table 2”) can be set by the potential setting circuit 61. The configuration of the potential setting circuit 61 will be described in each of FIGS. 2 to 4.

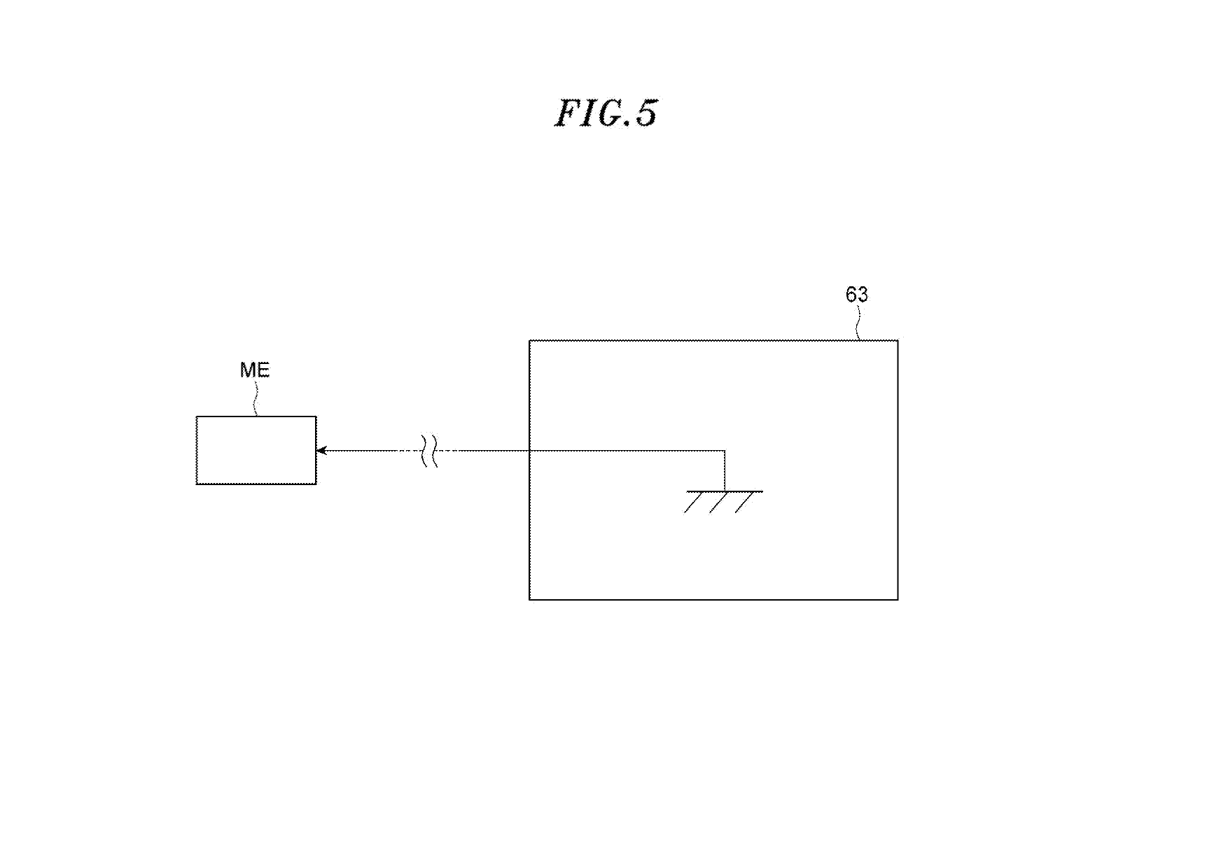

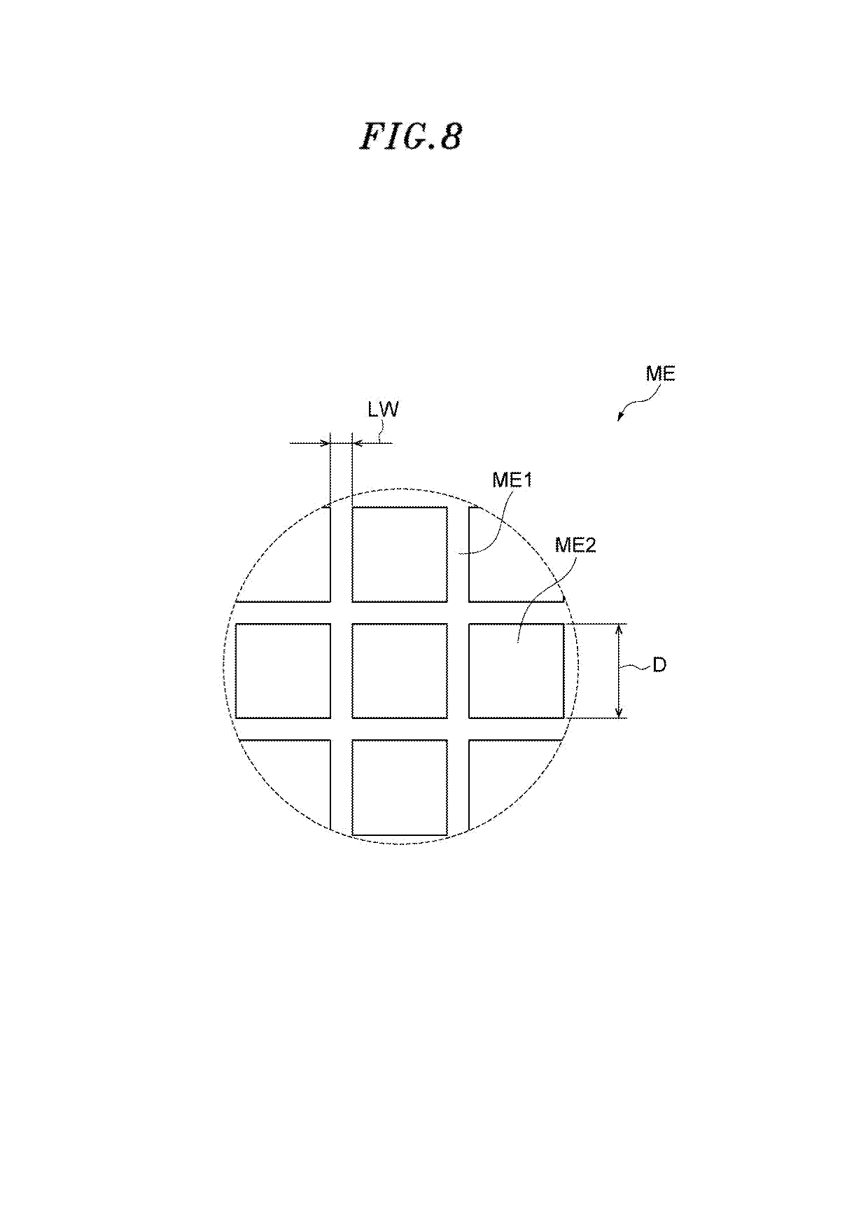

A planar electrode ME is a conductor configured by combining a plurality of conductive wires in a planar shape. The planar electrode ME may be, e.g., a conductor configured by arranging a plurality of conductive wires in a mesh pattern, a conductor configured by arranging a plurality of conductive wires without intersecting each other (substantially in parallel), or the like. The planar electrode ME is provided in a processing space 15 between the shower head 10 and the placing table 2, and extends along a surface 2a of the placing table 2. The potential of the planar electrode ME can be set by the potential setting circuit 63. The configuration of the potential setting circuit 63 will be described with reference to each of FIGS. 5 to 7. A configuration example of the planar electrode ME including multiple conductive wires arranged in a mesh pattern will be described with reference to FIG. 8.

The placing table 2 may have a heating mechanism or a cooling mechanism (both not shown) depending on plasma processing. A plurality of lift pins (not shown) may be inserted into the placing table 2 to be able to protrude from and retract below the upper surface of the placing table 2. The wafer W is transferred to and from the placing table 2 by raising and lowering the plurality of lift pins by a lifting mechanism (not shown).

An opening is provided in an upper portion of the processing chamber 1, and the shower head 10 is fitted into the opening via the insulating member 9 to face the placing table 2. The shower head 10 is a conductor, is electrically connected to the high-frequency power supply 30, is configured to receive a voltage applied from the high-frequency power supply 30, and serves as an upper electrode.

The shower head 10 is electrically connected to the high-frequency power supply 30 via the matching device 32, the power supply line 33, and the shaping circuit 34. The power supply line 33 electrically connects the high-frequency power supply 30 and the shower head 10 to each other. Positive voltage components of the high-frequency voltage outputted from the high-frequency power supply 30 via the matching device 32 are cut by the shaping circuit 34. As a result, the shaping circuit 34 generates a shaped high-frequency voltage. The shaped high-frequency voltage is applied to the shower head 10.

The matching device 32 is provided in the power supply line 33, and is electrically connected between the high-frequency power supply 30 and the shaping circuit 34. The matching device 32 is configured to match a load impedance to an internal impedance (or an output impedance) of the high-frequency power supply 30.

The shaping circuit 34 is provided in the power supply line 33, and is electrically connected between the matching device 32 and the shower head 10. The shaping circuit 34 is configured to supply, to the shower head 10, a shaped high-frequency voltage generated by cutting the positive voltage component of the high-frequency voltage supplied from the high-frequency power supply 30.

The shaping circuit 34 includes a capacitor 34a and a diode 34b. The capacitor 34a is provided between the matching device 32 and the shower head 10, and a portion of the power supply line 33 between the capacitor 34a and the shower head 10 is grounded via the diode 34b. In other words, one end of the capacitor 34a is electrically connected to the high-frequency power supply 30 via the matching device 32, and the other end of the capacitor 34a is electrically connected to the shower head 10. An anode of the diode 34b is electrically connected to the capacitor 34a and the shower head 10 via the power supply line 33. A cathode of the diode 34b is grounded.

The overall shape of the shower head 10 that is an upper electrode (hereinafter, simply referred to as “shower head 10”) may be cylindrical. The shower head 10 includes a main body 11 having an opening at a lower part thereof, and a shower plate 12 provided to close the opening of the main body 11. An internal space between the main body 11 and the shower plate 12 provides a gas diffusion space. The shower plate 12 is provided with the plurality of gas injection holes 13.

The shower head 10 is provided with the gas introducing holes 14, and a processing gas for plasma processing supplied from the gas supply part 20 is introduced into the shower head 10 through the gas introducing hole 14.

The gas supply part 20 is configured to supply a processing gas into the shower head 10. The processing gas introduced into the shower head 10 can be supplied from the gas injection holes 13 to the processing space 15.

The gas supply part 20 can supply a plurality of gases, such as a processing gas for plasma processing, a plasma generation gas, a purge gas, and the like. An appropriate gas is selected as the processing gas depending on the plasma processing to be performed. For example, the processing gas may include a gas that is used for film formation and provides a material of a film to the wafer W. The gas supply part 20 includes a plurality of gas supply sources and a plurality of gas supply lines (both not shown), and the gas supply lines are provided with flow rate controllers such as valves and mass flow controllers (both not shown).

The exhaust port 41 is provided at the bottom wall of the processing chamber 1, and the exhaust device 43 is connected to the exhaust port 41 via the exhaust line 42. The exhaust device 43 includes an automatic pressure control valve and a vacuum pump (both not shown). The inside of the processing chamber 1 is exhausted by the exhaust device 43, and the interior of the processing chamber 1 can be maintained at a preset vacuum level.

A transfer port (not shown) for loading and unloading the wafer W into and from the processing chamber 1 is provided in the sidewall of the processing chamber 1. The transfer port is opened and closed by a gate valve (not shown).

The valves and the flow rate controllers of the gas supply part 20, and the high-frequency power supply are controlled by the controller 50. The controller 50 controls various processes performed by the plasma processing apparatus 100.

The configurations of the potential setting circuit 61 and the potential setting circuit 63 will be described in detail with reference to FIGS. 2 to 7. FIGS. 2 to 4 are diagrams showing the configuration of the potential setting circuit 61 for setting the potential of the placing table 2, and FIGS. 5 to 7 are diagrams showing the configuration of the potential setting circuit 63 for setting the potential of the planar electrode ME.

### Example 1

The plasma processing apparatus 100 according to Example 1 includes the potential setting circuit 61 having the configuration shown in FIG. 2 and the potential setting circuit 63 having the configuration shown in FIG. 5. The potential setting circuit 61 shown in FIG. 2 is configured to ground the placing table 2. The potential setting circuit 63 shown in FIG. 5 is configured to ground the planar electrode ME. The planar electrode ME, which is a mesh-shaped conductor, is provided in the processing space 15, and extends along the surface 2a of the placing table 2. The potential setting circuit 63 is configured to set the potential of the planar electrode ME to a ground potential. Therefore, in the processing space 15, a current path is formed along a direction PS from the planar electrode ME at the ground potential toward the shower head 10, without being formed along the radial direction of the wafer W. Accordingly, no radial potential difference occurs on the surface 2a of the wafer W, and damage to the wafer W that may be caused by the potential difference can be reduced.

### Example 2

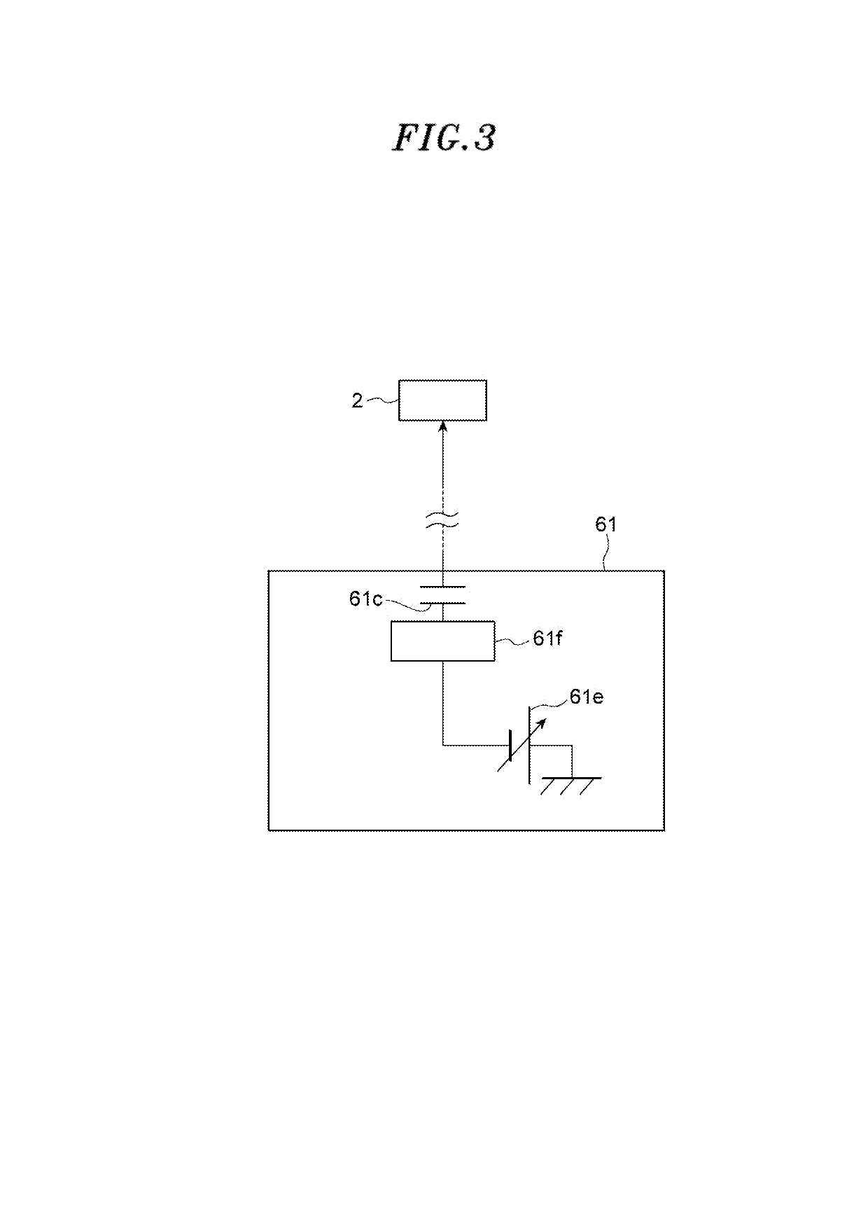

The plasma processing apparatus 100 according to Example 2 includes the potential setting circuit 61 having the configuration shown in FIG. 3, and the potential setting circuit 63 having the configuration shown in FIG. 5. The potential setting circuit 61 shown in FIG. 3 includes a capacitor 61c, a DC power supply 61e, and a pulse generator 61f. One end of the pulse generator 61f is electrically connected to the placing table 2 via the capacitor 61c. The other end of the pulse generator 61f is electrically connected to a negative electrode of a variable DC power supply 61e capable of adjusting a DC voltage output. The positive electrode of the DC power supply 61e is grounded. The planar electrode ME, which is a mesh-shaped conductor, is provided in the processing space 15 and extends along the surface 2a of the placing table 2. The potential setting circuit 63 is configured to set the potential of the planar electrode ME to a ground potential. Therefore, in the processing space 15, a current path is formed along the direction PS from the planar electrode ME at the ground potential toward the shower head 10, without being formed along the radial direction of the wafer W. Accordingly, no radial potential difference occurs on the surface 2a of the wafer W, and damage to the wafer W that may be caused by the potential difference can be reduced. Further, the potential setting circuit 61 for setting the potential of the placing table 2 is configured to shape the DC voltage supplied from the DC power supply 61e into a pulse wave by the pulse generator 61f and then apply the pulse wave to the placing table 2. As a result, the energy of ions traveling from the plasma excited by the high-frequency power supply 30 toward the placing table 2 can be adjusted by the potential setting circuit 61. In this manner, in Example 2, the potential setting circuit 61 can be regarded as a bias voltage application circuit.

### Example 3

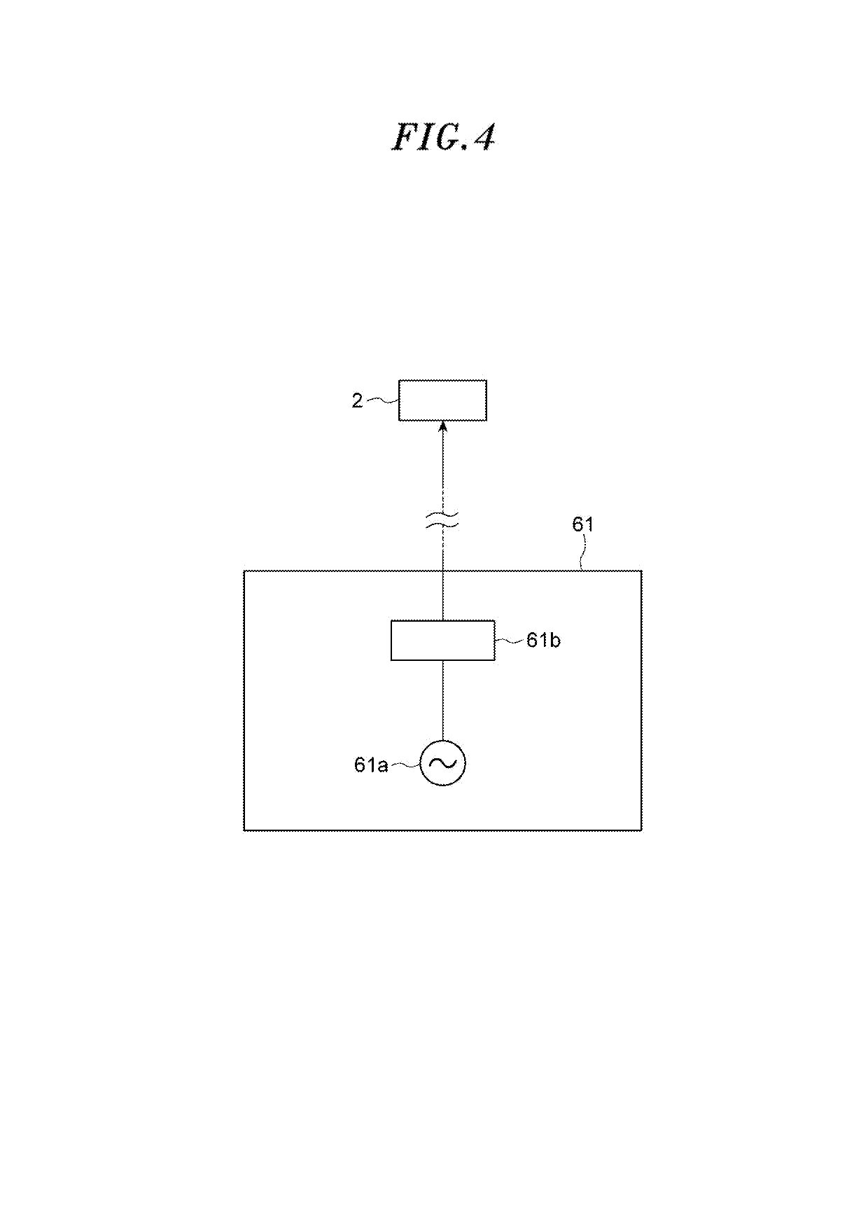

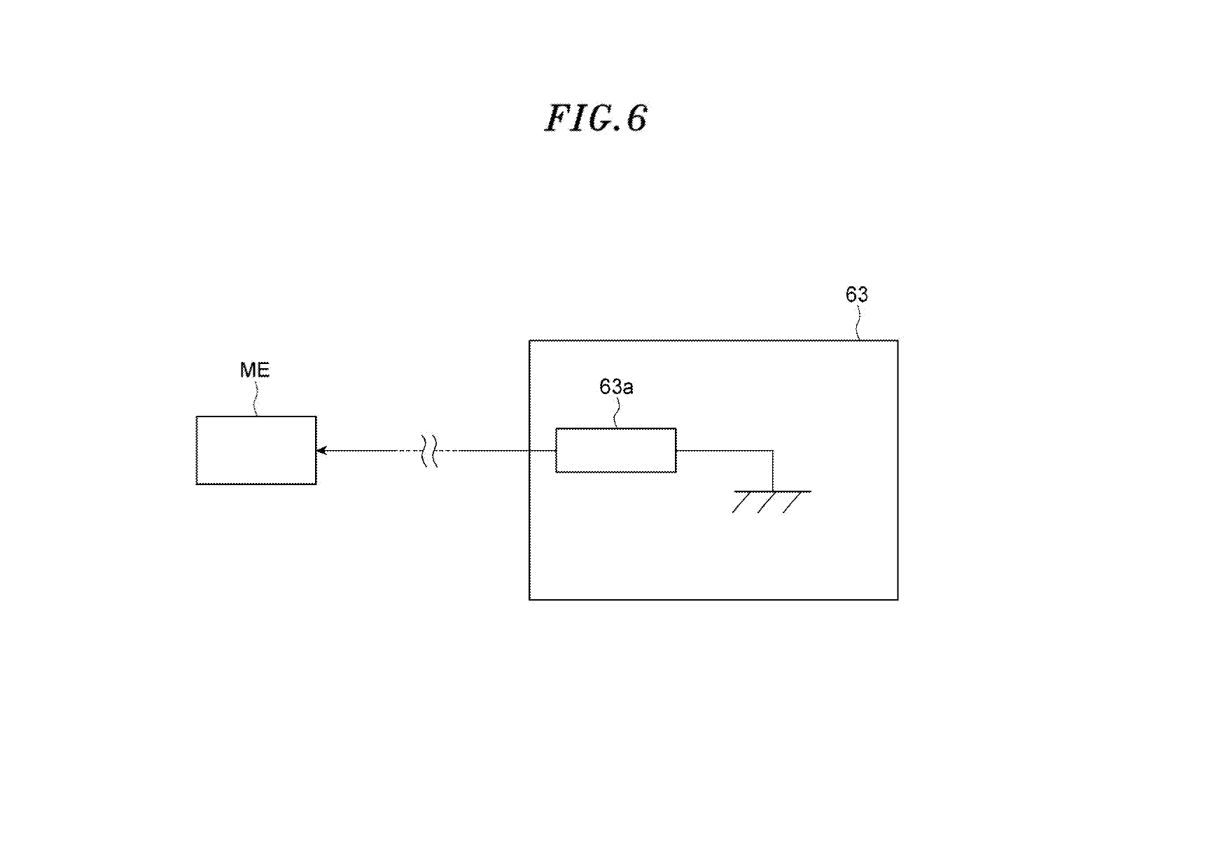

The plasma processing apparatus 100 according to Example 3 includes the potential setting circuit 61 having the configuration shown in FIG. 4, and the potential setting circuit 63 having the configuration shown in FIG. 6. The potential setting circuit 61 shown in FIG. 4 includes a high-frequency power supply 61a and a matching device 61b. The high-frequency power supply 61a is electrically connected to the placing table 2 via the matching device 61b. The potential setting circuit 63 having the configuration shown in FIG. 6 includes a filter circuit 63a. The filter circuit 63a has one end electrically connected to the planar electrode ME, and is configured to prevent a voltage having the frequency of the high-frequency voltage supplied from the high-frequency power supply 61a from being conducted to the ground. The other end of the filter circuit 63a is grounded. The filter circuit 63a may be, for example, an LC circuit. The planar electrode ME, which is a mesh-shaped conductor, is provided in the processing space 15, and extends along the surface 2a of the placing table 2. As a result, a current path due to high-frequency power applied from the high-frequency power supply 30 to the shower head 10 is formed along the direction PS from the planar electrode ME toward the shower head 10. Accordingly, no radial potential difference occurs on the surface 2a of the wafer W, and damage to the wafer W that may be caused by the potential difference can be reduced. Further, the potential of the planar electrode ME follows the voltage changes of the high-frequency voltage supplied from the high-frequency power supply 61a due to the operation of the filter circuit 63a. Therefore, the high-frequency power supply 61a forms a current path between itself and the shower head 10 without passing through the planar electrode ME. As a result, the energy of ions traveling from plasma excited by the high-frequency power supply 30 toward the placing table 2 can be adjusted by the high-frequency power supply 61a. In this manner, in Example 3, the potential setting circuit can be regarded as a bias voltage application circuit.

### Example 4

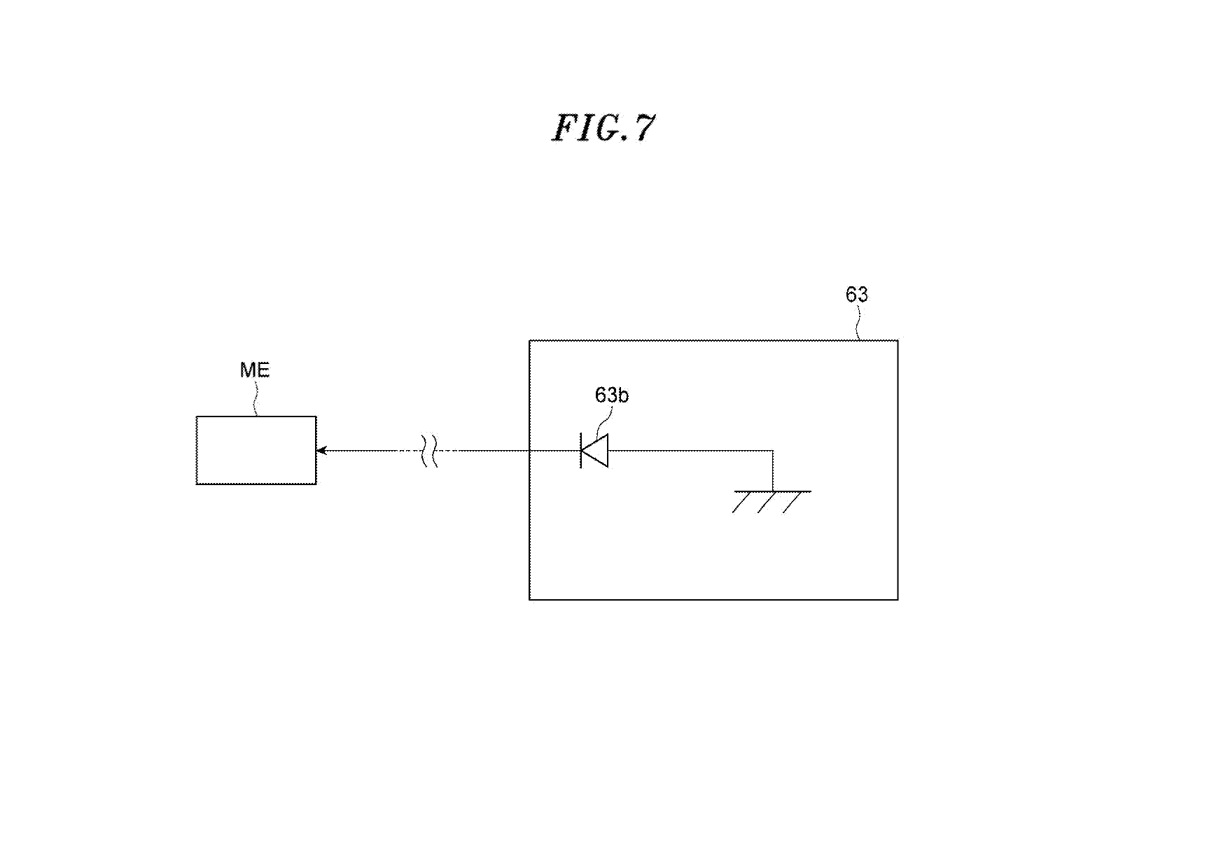

The plasma processing apparatus 100 according to Example 4 includes the potential setting circuit 61 having the configuration shown in FIG. 4, and the potential setting circuit 63 having the configuration shown in FIG. 7. The potential setting circuit 63 shown in FIG. 7 includes a diode 63b. A cathode of the diode 63b is electrically connected to the planar electrode ME. An anode of the diode 63b is grounded. The planar electrode ME, which is a mesh-shaped conductor, is provided in the processing space 15, and extends along the surface 2a of the placing table 2. The potential of the planar electrode ME follows voltage changes of a high-frequency voltage supplied from the high-frequency power supply 61a. Therefore, in the processing space 15, a current path is formed along the direction PS from the planar electrode ME having a potential following the voltage changes of the high-frequency voltage supplied from the high-frequency power supply 61a toward the shower head 10, without being formed along the radial direction of the wafer W. Accordingly, no radial potential difference occurs on the surface 2a of the wafer W, and damage to the wafer W that may be caused by the potential difference can be reduced.

A configuration example of the planar electrode ME used in Examples 1 to 4 described above is shown in FIG. 8. FIG. 8 is an enlarged view illustrating a portion of the configuration of the planar electrode ME including a plurality of conductive wires arranged in a mesh shape.

A wire diameter LW of a conductive wire ME1 of a planar electrode ME needs to be sufficiently large to allow a current to flow. Further, it is preferable that the wire diameter LW is sufficiently smaller than a distance between the planar electrode ME and the wafer W placed on the placing table 2. In this case, the wire diameter LW of the conductive wires ME1 of the planar electrode ME may be within a range of 0.3 mm or more and 10 mm or less, for example.

It is preferable that the distance between the planar electrode ME and the wafer W placed on the placing table 2 is sufficiently greater than the wire diameter LW. In this case, the planar electrode ME may be located within a range of 1 mm or more and 200 mm or less from the wafer W placed on the placing table 2, for example.

It is preferable that an aperture D of an opening ME2 of the planar electrode ME is sufficiently greater than a thickness of a sheath region formed between the wafer W and a plasma bulk in order to allow positive ions to pass through. Further, it is preferable that the aperture D of the opening ME2 is sufficiently less than a diameter of the wafer W so as not to form potential distribution on the wafer W. In this case, the aperture D of the openings ME2 may be within a range of 1 mm or more and 60 mm or less, for example.

In the case of the planar electrode ME configured by arranging a plurality of conductive wires along a common plane without intersecting each other (substantially in parallel), the wire diameter of the conductive wires may be within a range of 0.1 mm or more and 10 mm or less, for example, and a distance/spacing between adjacent conductive wires may be within a range of 1 mm or more and 60 mm or less, for example. In this case, the planar electrode ME may be located within a range of 1 mm or more and 200 mm or less from the wafer W placed on the placing table 2, for example.

While various embodiments have been described above, the present disclosure is not limited to the above-described embodiments, and various additions, omissions, substitutions and changes may be made. Further, other embodiments can be implemented by combining elements in different embodiments.

Here, various exemplary embodiments included in the present disclosure will be described in the following [E1] to [E13].

### E1

A plasma processing apparatus comprising:

a processing chamber;

a first high-frequency power supply;

a shower head electrically connected to the first high-frequency power supply and configured to receive a voltage applied from the first high-frequency power supply, the shower head serving as an upper electrode;

a shaping circuit configured to supply, to the shower head, a shaped high-frequency voltage generated by cutting a positive voltage component of a high-frequency voltage supplied from the first high-frequency power supply;

a placing table provided below the shower head and configured to support a wafer, the placing table serving as a lower electrode;

a planar electrode provided in a space between the shower head and the placing table, the planar electrode extending along a surface of the placing table and comprising a plurality of conductive wires combined in a planar shape;

a first potential setting circuit configured to set a potential of the planar electrode; and

a second potential setting circuit configured to set a potential of the placing table.

### E2

The plasma processing apparatus of [E1], wherein the shaping circuit includes a first capacitor and a first diode,

one end of the first capacitor is electrically connected to the high-frequency power supply,

the other end of the first capacitor is electrically connected to the shower head,

an anode of the first diode is electrically connected to the first capacitor and the shower head, and

a cathode of the first diode is grounded.

### E3

The plasma processing apparatus of [E1] or [E2], wherein the first potential setting circuit is configured to ground the planar electrode.

### E4

The plasma processing apparatus of [E3], wherein the second potential setting circuit is configured to ground the placing table.

### E5

The plasma processing apparatus of [E3], wherein the second potential setting circuit includes a DC power supply, a pulse generator, and a capacitor, and is configured to shape a DC voltage supplied from the DC power supply into a pulse wave by the pulse generator and to apply the pulse wave to the placing table,

one end of the pulse generator is electrically connected to the placing table via the capacitor,

the other end of the pulse generator is electrically connected to a negative electrode of the DC power supply, and

a positive electrode of the DC power supply is grounded.

### E6

The plasma processing apparatus of [E1] or [E2], wherein the second potential setting circuit includes a third high-frequency power supply,

the third high-frequency power supply is electrically connected to the placing table,

the first potential setting circuit includes a filter circuit having one end electrically connected to the planar electrode and configured to prevent conduction of a voltage having a frequency of a high-frequency voltage supplied from the third high-frequency power supply, and

the other end of the filter circuit is grounded.

### E7

The plasma processing apparatus of [E1] or [E2], wherein the second potential setting circuit includes a third high-frequency power supply,

the third high-frequency power supply is electrically connected to the placing table,

the first potential setting circuit includes a second diode,

a cathode of the second diode is electrically connected to the planar electrode, and

an anode of the second diode is grounded.

### E8

The plasma processing apparatus of any one of [E1] to [E7], wherein the planar electrode is positioned within a range of 1 mm or more and 200 mm or less from the wafer placed on the placing table.

### E9

The plasma processing apparatus of any one of [E1] to [E8], wherein the planar electrode includes the plurality of conductive wires arranged in a mesh shape, or includes the plurality of conductive wires arranged along a common plane without intersecting each other.

### E10

The plasma processing apparatus of [E9], wherein a wire diameter of each of the plurality of conductive wires arranged in the mesh shape in the planar electrode is within a range of 0.3 mm or more and 10 mm or less.

### E11

The plasma processing apparatus of [E9], wherein an aperture of an opening of the planar electrode including the plurality of conductive wires arranged in the mesh shape is within a range of 1 mm or more and 60 mm or less.

### E12

The plasma processing apparatus of [E9], wherein a wire diameter of each of the plurality of conductive wires arranged along the common plane without intersecting each other in the planar electrode is within a range of 0.1 mm or more and 10 mm or less.

### E13

The plasma processing apparatus of [E9] or [E12], wherein a spacing between adjacent conductive wires in the planar electrode including the plurality of conductive wires arranged along the common plane without intersecting each other is within a range of 1 mm or more and 60 mm or less.

From the above description, it will be appreciated that various embodiments of the present disclosure have been described herein for purposes of illustration, and that various changes can be made without departing from the scope and spirit of the present disclosure. Therefore, the various embodiments disclosed herein are not intended to be limiting, with a true scope and spirit being indicated by the appended claims.

1. A plasma processing apparatus comprising:
a processing chamber;
a first high-frequency power supply;
a shower head electrically connected to the first high-frequency power supply and configured to receive a voltage applied from the first high-frequency power supply, the shower head serving as an upper electrode;
a shaping circuit configured to supply, to the shower head, a shaped high-frequency voltage generated by cutting a positive voltage component of a high-frequency voltage supplied from the first high-frequency power supply;
a placing table provided below the shower head and configured to support a wafer, the placing table serving as a lower electrode;
a planar electrode provided in a space between the shower head and the placing table, the planar electrode extending along a surface of the placing table and comprising a plurality of conductive wires combined in a planar shape;
a first potential setting circuit configured to set a potential of the planar electrode; and
a second potential setting circuit configured to set a potential of the placing table.

2. The plasma processing apparatus of claim 1, wherein the shaping circuit includes a first capacitor and a first diode,
one end of the first capacitor is electrically connected to the high-frequency power supply,
the other end of the first capacitor is electrically connected to the shower head,
an anode of the first diode is electrically connected to the first capacitor and the shower head, and
a cathode of the first diode is grounded.

3. The plasma processing apparatus of claim 1, wherein the first potential setting circuit is configured to ground the planar electrode.

4. The plasma processing apparatus of claim 3, wherein the second potential setting circuit is configured to ground the placing table.

5. The plasma processing apparatus of claim 3, wherein the second potential setting circuit includes a DC power supply, a pulse generator, and a capacitor, and is configured to shape a DC voltage supplied from the DC power supply into a pulse wave by the pulse generator and to apply the pulse wave to the placing table,
one end of the pulse generator is electrically connected to the placing table via the capacitor,
the other end of the pulse generator is electrically connected to a negative electrode of the DC power supply, and
a positive electrode of the DC power supply is grounded.

6. The plasma processing apparatus of claim 1, wherein the second potential setting circuit includes a third high-frequency power supply,
the third high-frequency power supply is electrically connected to the placing table,
the first potential setting circuit includes a filter circuit having one end electrically connected to the planar electrode and configured to prevent conduction of a voltage having a frequency of a high-frequency voltage supplied from the third high-frequency power supply, and
the other end of the filter circuit is grounded.

7. The plasma processing apparatus of claim 1, wherein the second potential setting circuit includes a third high-frequency power supply,
the third high-frequency power supply is electrically connected to the placing table,
the first potential setting circuit includes a second diode,
a cathode of the second diode is electrically connected to the planar electrode, and
an anode of the second diode is grounded.

8. The plasma processing apparatus of claim 1, wherein the planar electrode is positioned within a range of 1 mm or more and 200 mm or less from the wafer placed on the placing table.

9. The plasma processing apparatus of claim 1, wherein the planar electrode includes the plurality of conductive wires arranged in a mesh shape, or includes the plurality of conductive wires arranged along a common plane without intersecting each other.

10. The plasma processing apparatus of claim 9, wherein a wire diameter of each of the plurality of conductive wires arranged in the mesh shape in the planar electrode is within a range of 0.3 mm or more and 10 mm or less.

11. The plasma processing apparatus of claim 9, wherein an aperture of an opening of the planar electrode including the plurality of conductive wires arranged in the mesh shape is within a range of 1 mm or more and 60 mm or less.

12. The plasma processing apparatus of claim 9, wherein a wire diameter of each of the plurality of conductive wires arranged along the common plane without intersecting each other in the planar electrode is within a range of 0.1 mm or more and 10 mm or less.

13. The plasma processing apparatus of claim 9, wherein a spacing between adjacent conductive wires in the planar electrode including the plurality of conductive wires arranged along the common plane without intersecting each other is within a range of 1 mm or more and 60 mm or less.
